(19) United States
(12) Patent Application Publication
(10) Pub. No.: US 2008/0032510 A1
(43) Pub. Date: Feb. 7, 2008

(54) CMOS SION GATE DIELECTRIC PERFORMANCE WITH DOUBLE PLASMA NITRIDATION CONTAINING NOBLE GAS

(76) Inventor: Christopher Olsen, Fremont, CA (US)

Correspondence Address: PATTERSON & SHERIDAN, LLP, 3040 POST OAK BOULEVARD, SUITE 1500, HOUSTON, TX, 77056, US

(21) Appl. No.: 11/764,219

(22) Filed: Jun. 17, 2007

Related U.S. Application Data
(60) Provisional application No. 60/821,472, filed on Aug. 4, 2006.

(51) Int. Cl. H01L 21/31

(52) U.S. Cl. 438/770; 438/776; 257/E21.24

(57) ABSTRACT

A method of forming a layer comprising silicon and nitrogen on a substrate is provided. The layer may also include oxygen and be used as a silicon oxynitride gate dielectric layer. In one aspect, forming the layer includes exposing a silicon substrate to a plasma of nitrogen and a noble gas to incorporate nitrogen into an upper surface of the substrate, wherein the noble gas is argon, neon, krypton, or xenon. The layer is annealed and then exposed to a plasma of nitrogen to incorporate more nitrogen into the layer. The layer is then further annealed.

### CROSS-REFERENCE TO RELATED APPLICATIONS

This application claims benefit of U.S. provisional patent application Ser. No. 60/821,472, filed Aug. 4, 2006, which is herein incorporated by reference.

### BACKGROUND OF THE INVENTION

1. Field of the Invention

Embodiments of the present invention generally relate to a method of forming a gate dielectric layer. More particularly, embodiments of the invention relate to a method of forming a silicon oxynitride (SiON) gate dielectric layer.

2. Description of the Related Art

Integrated circuits are composed of many, e.g., millions, of devices such as transistors, capacitors, and resistors. Transistors, such as field effect transistors, typically include a source, a drain, and a gate stack. The gate stack typically includes a substrate, such as a silicon substrate, a gate dielectric, such as silicon dioxide, SiO₂, on the substrate, and a gate electrode, such as polycrystalline silicon, on the gate dielectric.

As integrated circuit sizes and the sizes of the transistors thereon decrease, the gate drive current required to increase the speed of the transistor has increased. Because the drive current increases as the gate capacitance increases, and capacitance is inversely proportional to the gate dielectric thickness, decreasing the dielectric thickness is one method of increasing the drive current.

Attempts have been made to reduce the thickness of SiO₂ gate dielectrics below 20 Å. However, it has been found that the use of thin SiO₂ gate dielectrics below 20 Å often results in undesirable effects on gate performance and durability. For example, boron from a boron doped gate electrode can penetrate through a thin SiO₂ gate dielectric into the underlying silicon substrate. Also, there is typically an increase in gate leakage, i.e., tunneling, with thin dielectrics that increases the amount of power consumed by the gate.

One method that has been used to address the problems with thin SiO₂ gate dielectrics is to incorporate nitrogen into the SiO₂ layer to form a silicon oxynitride (SiON or SiOₓN_{y}) gate dielectric. Incorporating nitrogen into the SiO₂ layer blocks boron penetration into the underlying silicon substrate and raises the dielectric constant of the gate dielectric, allowing the use of a thicker dielectric layer.

Plasma nitridation has been used to incorporate nitrogen into SiO₂ layers to form silicon oxynitride layers in essentially a one step process, with an optional post anneal. However, with such a single step nitridation process, it is difficult to control the concentration profile of the silicon oxynitride layer, such as the atomic nitrogen percent, through the thickness of the layer. Thus, there remains a need for a method of depositing silicon oxynitride layers.

### SUMMARY OF THE INVENTION

The present invention generally provides a method of forming a layer comprising silicon and nitrogen on a substrate. The layer comprising silicon and nitrogen may also comprise oxygen, and thus provide a silicon oxynitride layer that may be used as a gate dielectric layer.

In one embodiment, a method of forming a layer comprising silicon and nitrogen on a substrate comprises introducing a substrate comprising silicon into a chamber and then exposing the substrate in the chamber to a plasma of nitrogen and a noble gas to incorporate nitrogen into an upper surface of the substrate and form a layer comprising silicon and nitrogen on the substrate, wherein the noble gas is selected from the group consisting of argon, neon, krypton, and xenon. The layer comprising silicon and nitrogen is annealed. Annealing the layer may include exposing the layer to gas comprising oxygen gas at a temperature of between about 800° C. and about 1100° C. or exposing the layer to an inert gas at a temperature of between about 800° C. and about 1100° C. The layer is then exposed to a plasma of nitrogen to incorporate more nitrogen into the layer comprising silicon and nitrogen. The layer is then further annealed.

In another embodiment, a method of forming a layer comprising silicon and nitrogen on a substrate comprises introducing a substrate comprising silicon into a chamber and then exposing the substrate in the chamber to a plasma of nitrogen and argon to incorporate nitrogen into an upper surface of the substrate and form a layer comprising silicon and nitrogen on the substrate. The layer comprising silicon and nitrogen is annealed, and oxygen is introduced into the layer during the annealing. The layer is then exposed to a plasma of nitrogen to incorporate more nitrogen into the layer comprising silicon and nitrogen. The layer is then further annealed.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a flow chart depicting an embodiment of the invention.

FIGS. 2A-2E depict schematic cross-sectional views of a substrate structure at different stages of a process sequence according to an embodiment of the invention.

FIG. 3 is a graph showing the NMOS drive current for dielectric layers according to embodiments of the invention relative to the equivalent oxide thickness (EOT) of the layers.

FIG. 4 is a graph showing the PMOS drive current for dielectric layers according to embodiments of the invention relative to the equivalent oxide thickness (EOT) of the layers.

### DETAILED DESCRIPTION

Embodiments of the present invention provide a method of forming a layer comprising silicon and nitrogen. The layer comprising silicon and nitrogen may be a silicon oxynitride (SiON) layer that may be used as a gate dielectric layer. Gate stacks including silicon oxynitride layers according to embodiments of the invention have desirable drive currents in both NMOS and PMOS devices.

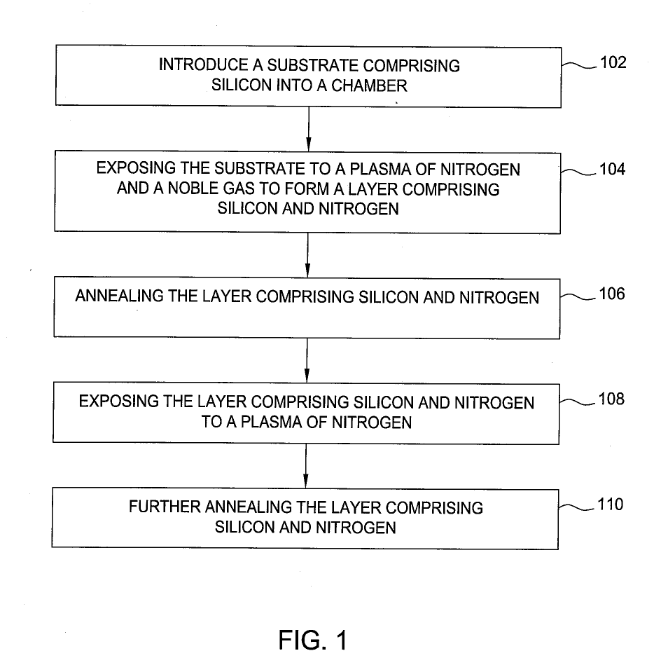

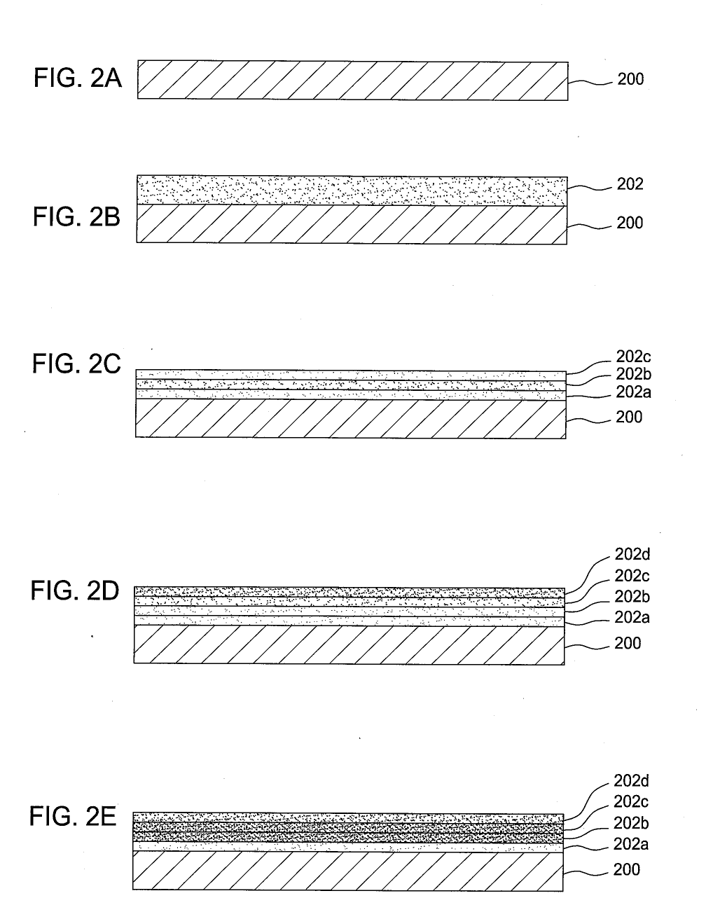

An embodiment of the invention will be described briefly with respect to the flow chart of FIG. 1 and will be further described below with respect to FIGS. 2A-2E.

A substrate comprising silicon is introduced into a chamber at step 102, as shown in FIG. 1. The substrate is exposed to a plasma of nitrogen and a noble gas, i.e., a nitrogen and noble gas-containing-plasma, to form a layer comprising silicon and nitrogen on the substrate, as shown in step 104. The layer comprising silicon and nitrogen is then annealed in step 106. The layer comprising silicon and nitrogen is then exposed to a plasma of nitrogen in step 108. In step 110, the layer comprising silicon and nitrogen is further annealed. Steps 104 and 108 may be described as plasma nitridation steps, as they incorporate nitrogen into a layer in the presence of a plasma. By using a sequence of multiple plasma nitridation and annealing steps, a layer comprising silicon and nitrogen, such as a silicon oxynitride layer, having a desired concentration profile may be obtained.

FIG. 2A shows an example of a substrate 200 that comprises silicon, as described above in step 102 of FIG. 1. The substrate 200 may be a 200 mm or 300 mm substrate or other substrate suitable for semiconductor or flat panel display processing. The substrate may be a silicon substrate such as a bare silicon wafer or substrate. Alternatively, the substrate may be a silicon substrate having an upper surface that is hydrogen-terminated or comprises a thin chemical oxide layer thereon. A hydrogen-terminated upper surface or a thin chemical oxide layer on the upper surface of the substrate may be created by a cleaning process that is performed on the silicon substrate before the substrate is introduced into the chamber in step 102. The cleaning process may be performed to remove a native oxide layer or other contaminants from the substrate before further processing. The cleaning process may be performed in either a single substrate or batch system. The cleaning process may be performed in an ultra-sonically enhanced bath.

In one embodiment, a cleaning process comprises exposing the substrate to a wet clean process. The wet clean process may include exposing the substrate to a solution comprising H₂O, NH₄OH, and H₂O₂, e.g., a SC-1 solution, that forms a thin chemical oxide layer on the upper surface of the substrate. Alternatively, the wet clean process may include an HF last clean in which the last step of the cleaning process includes exposing the substrate to a dilute solution of hydrofluoric acid (HF) and leaves a hydrogen-terminated upper surface on the substrate. The solution may have a concentration of about 0.1 to about 10.0 weight percent HF and be used at a temperature of about 20° C. to about 30° C. In an exemplary embodiment, the solution has about 0.5 weight percent of HF and a temperature of about 25° C. A brief exposure of the substrate to the solution may be followed by a rinse step in de-ionized water.

Returning to step 102, the chamber into which the substrate is introduced is a chamber that is capable of exposing the substrate to a plasma. The plasma may be produced using RF power, microwave power, or a combination thereof. The plasma may be produced using a quasi-remote plasma source, an inductive plasma source, a radial line slotted antenna (RLSA) source, or other plasma sources. The plasma may be continuous or pulsed.

An example of a chamber that can be used is a decoupled plasma nitridation (DPN) chamber. A DPN chamber is further described in U.S. Patent Application Publication No. 2004/0242021, entitled “Method and Apparatus for Plasma Nitridation of Gate Dielectrics Using Amplitude Modulated Radio Frequency Energy,” assigned to Applied Materials, Inc., published Dec. 2, 2004, and which is hereby incorporated by reference herein. One suitable decoupled plasma nitridation (DPN) chamber is the DPN CENTURA® chamber, which is commercially available from Applied Materials, Inc. of Santa Clara, Calif. An example of an integrated processing system that may include DPN CENTURA® chamber and be used to perform embodiments of the invention is the GATE STACK CENTURA® system, which is also available from Applied Materials, Inc. of Santa Clara, Calif.

Once in the chamber, the substrate 200 is exposed to a plasma of nitrogen and a noble gas to incorporate nitrogen into an upper surface of the substrate and form a layer 202 comprising silicon and nitrogen on the substrate, as shown in FIG. 2B. In one aspect, exposing the substrate to a plasma of nitrogen and a noble gas is a plasma nitridation process. The nitrogen in the plasma is provided by a nitrogen source, such as nitrogen gas (N₂). The noble gas may be argon (Ar), neon (Ne), krypton (Kr), or xenon (Xe). In one embodiment, the nitrogen source is nitrogen gas, and the noble gas is argon. The plasma may comprise between about 1% and about 80% of the noble gas, with the remainder provided by the nitrogen. An example of plasma processing conditions that may be used includes a flow of a nitrogen source, e.g., N₂, into the chamber at between about 10 sccm and about 2000 sccm, a flow of the noble gas, e.g., Ar, into the chamber at between about 10 sccm and about 2000 sccm, a chamber substrate support temperature of between about 20° C. and about 500° C., and a chamber pressure of between about 5 mTorr and about 1000 mTorr. The RF power may be provided at 13.56 MHz, with a continuous wave (CW) or pulsed plasma power of about 3 kW to about 5 kW. During pulsing, peak RF power, frequency and duty cycle are typically about 10 W to about 3000 W, about 2 kHz to about 100 kHz, and about 2 to about 50 percent, respectively. The plasma nitridation may be performed for about 1 to about 180 seconds. In one embodiment, N₂ is provided at about 200 sccm, and about 1000 W RF power is pulsed at about 10 kHz with a duty cycle of about 5 percent applied to an inductive plasma source, at about 25° C. and about 20 mTorr, for about 15 to about 180 seconds on a chemical oxide surface. In an additional embodiment, N₂ is provided at about 200 sccm, and about 1000 W RF power is pulsed at about 10 kHz with a duty cycle of about 5 percent applied to an inductive plasma source, at about 25° C. and about 80 mTorr, for about 15 sec on a hydrogen terminated surface.

After the layer 202 comprising silicon and nitrogen is formed, the layer is annealed. Annealing the layer 202 forms different sublayers in layer 202, as shown in FIG. 2C. Sublayer 202a is adjacent the substrate 202, sublayer 202c is furthest away from substrate 202, and sublayer 202b is between sublayers 202a and 202c. Sublayer 202b has a higher nitrogen concentration than sublayers 202a and 202c, and sublayers 202a and 202c have a lower nitrogen concentration than layer 202 has prior to annealing. Annealing the layer 202 also densifies the layer such that in the subsequent exposure of the layer 202 to a nitrogen-containing plasma (step 108), the nitrogen does not penetrate the layer 202 too deeply and contaminate the underlying substrate 202, which can harm a gate device that includes layers 202 and 200 as a gate dielectric layer and an underlying silicon channel, respectively. The annealing may be performed in a chamber such as a RADIANCE® chamber or a RadiancePlus RTP chamber, both of which are available from Applied Materials, Inc. of Santa Clara, Calif.

In one embodiment, annealing the layer comprising silicon and nitrogen comprises exposing the layer to a lightly oxidizing ambient atmosphere, such as a low pressure oxidizing ambient, such as a low pressure O₂ or O₂ diluted in N₂ ambient, wherein the O₂ partial pressure is between about 1 mTorr and about 100 Torr. The layer may be annealed at a substrate temperature between about 800° C. and about 1100° C. for between about 5 seconds and about 180 seconds. The O₂ may be introduced into the chamber at a flow rate of between about 2 sccm and about 5000 sccm, such as about 500 sccm. In one embodiment, O₂ is provided at about 500 sccm while maintaining the temperature at about 1000° C. and a pressure of about 0.1 Torr for about 15 seconds.

In another embodiment, annealing the layer comprising silicon and nitrogen comprises exposing the layer to an inert gas, such as nitrogen, argon, or a combination thereof, at a temperature of between about 800° C. and about 1100° C.

In another embodiment, the annealing may be performed by providing a wet oxidation environment. This process, known as in situ steam generation (ISSG), is commercially available from Applied Materials, Inc. of Santa Clara, Calif. The ISSG process includes heating the substrate surface to about 700° C. to 1000° C. in an environment with 500 sccm to 5000 sccm oxygen and 10 sccm to 1000 sccm hydrogen, and at a pressure of 0.5 to 18.0 Torr. Preferably, hydrogen is less than 20 percent of the total gas flow of the mixture of oxygen and hydrogen. The period of exposure to the gas mixture is about 5 to about 180 seconds. In one embodiment, oxygen is provided at 980 sccm, hydrogen is provided at 20 sccm, the substrate surface temperature is 800° C., the chamber pressure is 7.5 Torr, and the period of exposure is about 15 seconds.

After the layer comprising silicon and nitrogen is annealed, the layer is exposed to a plasma of nitrogen, as shown in step 108 of FIG. 1. Exposing the layer to the plasma of nitrogen incorporates an additional amount of nitrogen into the layer and thus increases the atomic percent of nitrogen in the layer. As shown in FIG. 2D, an additional sublayer 202d of the silicon and nitrogen containing layer 202 is formed at the surface of the silicon and nitrogen containing layer 202 and has a higher nitrogen concentration than sublayers 202a-202c.

The plasma of nitrogen may be provided by a nitrogen source, such as nitrogen gas (N₂), nitrous oxide (N₂O), or nitric oxide (NO). Optionally, the plasma of nitrogen may also comprise a noble gas, such as argon, neon, krypton, or xenon. The plasma may be produced using RF power, microwave power, or a combination thereof. The plasma may be produced using a quasi-remote plasma source, an inductive plasma source, a radial line slotted antenna (RLSA) source, or other plasma sources. The plasma may be continuous or pulsed. The layer may be exposed to the plasma in a DPN chamber such as a DPN CENTURA® chamber.

An example of plasma processing conditions that may be used includes a flow of a nitrogen source, e.g., N₂, into the chamber at between about 10 sccm and about 2000 sccm, a chamber substrate support temperature of between about 20° C. and about 500° C., and a chamber pressure of between about 5 mTorr and about 1000 mTorr. The RF power may be provided at 13.56 MHz, with a continuous wave (CW) or pulsed plasma power of about 3 kW to about 5 kW. During pulsing, peak RF power, frequency and duty cycle are typically about 10 W to about 3000 W, about 2 kHz to about 100 kHz, and about 2 to about 50 percent, respectively. The plasma nitridation may be performed for about 1 to about 180 seconds. In one embodiment, N₂ is provided at about 200 sccm, and about 1000 W RF power is pulsed at about 10 kHz with a duty cycle of about 5 percent applied to an inductive plasma source, at about 25° C. and about 20 mTorr, for about 15 to about 180 seconds.

After the layer 202 comprising silicon and nitrogen is exposed to the plasma of nitrogen, the layer is further annealed, as shown in step 110. As shown in FIG. 2E, the further annealing alters the nitrogen concentration profile of the layer 202 such that sublayers 202b and 202c have a higher nitrogen concentration than the sublayers 202a and 202d. One benefit of reducing the nitrogen concentration in the sublayer 202a is that it reduces the nitrogen concentration at the interface between the layer 202 and the silicon substrate 200, which is desirable when the layer 202 is a gate dielectric layer and the silicon substrate includes a silicon channel of a gate transistor, as reducing the nitrogen concentration at the gate dielectric-silicon channel interface reduces the fixed charge and interface state density. The further annealing may be performed in a chamber such as a RADIANCE® chamber or a RadiancePlus RTP chamber, both of which are available from Applied Materials, Inc. of Santa Clara, Calif.

In one embodiment, annealing the layer comprising silicon and nitrogen comprises exposing the layer to a lightly oxidizing ambient atmosphere, such as a low pressure oxidizing ambient, such as a low pressure O₂ or O₂ diluted in N₂ ambient, wherein the O₂ partial pressure is between about 1 mTorr and about 100 Torr. The layer may be annealed at a substrate temperature between about 800° C. and about 1100° C. for between about 5 seconds and about 180 seconds. The O₂ may be introduced into the chamber at a flow rate of between about 2 sccm and about 5000 sccm, such as about 500 sccm. In one embodiment, O₂ is provided at about 500 sccm while maintaining the temperature at about 1000° C. and a pressure of about 0.1 Torr for about 15 seconds.

In another embodiment, annealing the layer comprising silicon and nitrogen comprises exposing the layer to an inert gas, such as nitrogen, argon, or a combination thereof, at a temperature of between about 800° C. and about 1100° C.

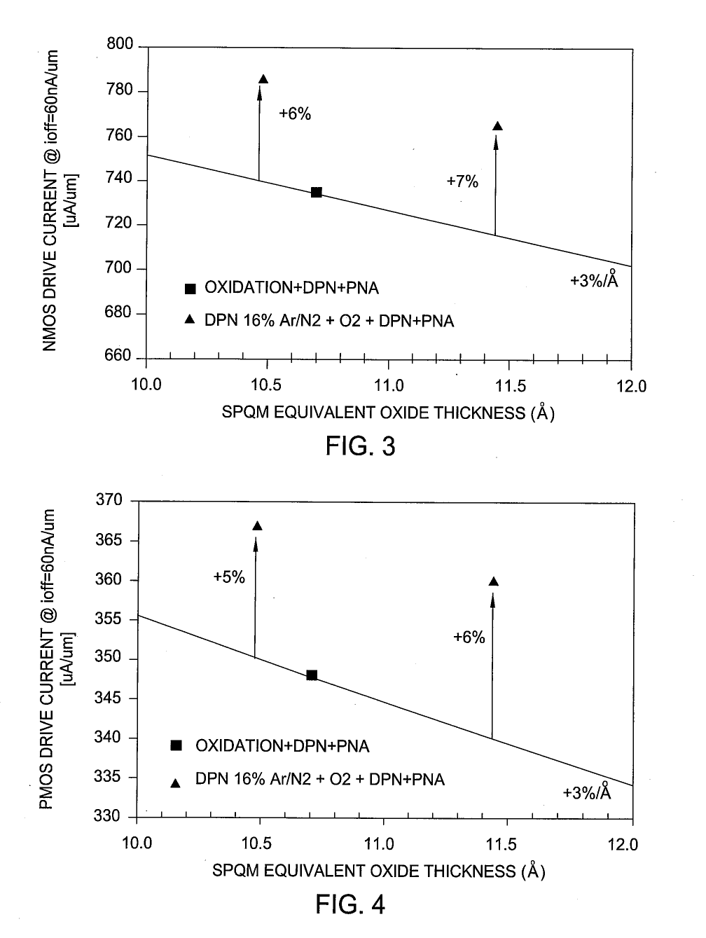

FIGS. 3 and 4 respectively show the NMOS drive current versus gate dielectric layer equivalent oxide thickness and the PMOS drive current versus gate dielectric layer equivalent oxide thickness for gate stacks including silicon oxynitride gate dielectric layers formed according to embodiments of the invention as well as for gate stacks including silicon oxynitride gate dielectric layers formed according to another method. The gate dielectric layers formed according to another method were formed by a process comprising oxidation of a silicon substrate, plasma nitridation of the silicon substrate (decoupled plasma nitridation, DPN), and annealing the substrate (post-nitridation anneal, PNA). The gate dielectric layers formed according to embodiments of the invention were formed by a process comprising plasma nitridation of a silicon substrate in a 16% argon/nitrogen plasma, annealing the substrate at a high temperature in the presence of oxygen (O₂), plasma nitridation of the substrate in a nitrogen plasma, and annealing the substrate at a high temperature in a reduced pressure oxygen ambient.

FIGS. 3 and 4 show that there was approximately a 6% improvement in drive current in both NMOS and PMOS devices that included gate dielectric layers according to embodiments of the invention relative to gate dielectric layers formed by a single plasma nitridation of a silicon oxide layer. It was also found that gate dielectric layers formed according to embodiments of the invention had approximately a 3% improvement over devices that included gate dielectric layers that were formed by a process comprising plasma nitridation of a silicon substrate in a nitrogen plasma that did not include argon or other noble gas, annealing the substrate at a high temperature in the presence of oxygen (O₂), plasma nitridation of the substrate in a nitrogen plasma, and annealing the substrate at a high temperature. It is believed that using a plasma comprising argon or another heavy inert gas, such as neon, krypton, or xenon, in addition to nitrogen during the first plasma nitridation of a substrate improves the drive current by improving the interface between the silicon substrate and the silicon and nitrogen layer formed thereon, e.g., a silicon oxynitride layer.

While the foregoing is directed to embodiments of the present invention, other and further embodiments of the invention may be devised without departing from the basic scope thereof, and the scope thereof is determined by the claims that follow.

What is claimed is:

1. A method of forming a layer comprising silicon and nitrogen on a substrate, comprising:
introducing a substrate comprising silicon into a chamber;
exposing the substrate in the chamber to a plasma of nitrogen and a noble gas to incorporate nitrogen into an upper surface of the substrate and form a layer comprising silicon and nitrogen on the substrate, wherein the noble gas is selected from the group consisting of argon, neon, krypton, and xenon;
annealing the layer comprising silicon and nitrogen;
exposing the layer comprising silicon and nitrogen to a plasma of nitrogen to incorporate more nitrogen into the layer comprising silicon and nitrogen; and then
further annealing the layer comprising silicon and nitrogen.

2. The method of claim 1, wherein the annealing the layer comprising silicon and nitrogen comprises introducing oxygen into the layer.

3. The method of claim 1, wherein the nitrogen is provided by nitrogen gas (N₂) as a nitrogen source.

4. The method of claim 1, wherein the plasma is generated using RF power, microwave power, or a combination thereof.

5. The method of claim 1, wherein the annealing and further annealing each comprise exposing the layer comprising silicon and nitrogen to a gas comprising oxygen gas (O₂) at a temperature of between about 800° C. and about 1100° C.

6. The method of claim 1, wherein one or more of the annealing and further annealing comprises exposing the layer comprising silicon and nitrogen to an inert gas at a temperature of between about 800° C. and about 1100° C.

7. A method of forming a layer comprising silicon and nitrogen on a substrate, comprising:
introducing a substrate comprising silicon into a chamber, wherein the substrate has an upper surface that is hydrogen-terminated or comprises a thin chemical oxide layer thereon;
exposing the substrate in the chamber to a plasma of nitrogen and a noble gas to incorporate nitrogen into the upper surface of the substrate and form a layer comprising silicon and nitrogen on the substrate, wherein the noble-gas is selected from the group consisting of argon, neon, krypton, and xenon;
annealing the layer comprising silicon and nitrogen, wherein oxygen is introduced into the layer during the annealing;
exposing the layer comprising silicon and nitrogen to a plasma of nitrogen to incorporate more nitrogen into the layer comprising silicon and nitrogen; and then
further annealing the layer comprising silicon and nitrogen.

8. The method of claim 7, wherein the nitrogen is provided by nitrogen gas (N₂) as a nitrogen source.

9. The method of claim 7, further comprising cleaning the substrate before introducing the substrate into the chamber.

10. The method of claim 9, wherein cleaning the substrate comprises a wet clean process.

11. The method of claim 10, wherein the wet clean process includes exposing the substrate to a solution comprising H₂O, NH₄OH, and H₂O₂.

12. The method of claim 11, wherein cleaning the substrate comprises exposing the substrate to HF.

13. The method of claim 7, wherein the substrate has an upper surface that comprises a thin chemical oxide layer having a thickness of between about 3 Å and about 5 Å thereon.

14. A method of forming a layer comprising silicon and nitrogen on a substrate, comprising:
introducing a substrate comprising silicon into a chamber;
exposing the substrate in the chamber to a plasma of nitrogen and argon to incorporate nitrogen into an upper surface of the substrate and form a layer comprising silicon and nitrogen on the substrate;
annealing the layer comprising silicon and nitrogen, wherein oxygen is introduced into the layer during the annealing;
exposing the layer comprising silicon and nitrogen to a plasma of nitrogen to incorporate more nitrogen into the layer comprising silicon and nitrogen; and then
further annealing the layer comprising silicon and nitrogen.

15. The method of claim 14, further comprising cleaning the substrate before introducing the substrate into the chamber.

16. The method of claim 15, wherein the cleaning forms an upper surface of the substrate that is hydrogen-terminated or comprises a thin chemical oxide layer thereon.

17. The method of claim 16, wherein the substrate has an upper surface that comprises a thin chemical oxide layer having a thickness of between about 3 Å and about 5 Å thereon.

18. The method of claim 14, wherein the nitrogen is provided by nitrogen gas (N₂) as a nitrogen source.

19. The method of claim 14, wherein the annealing and further annealing each comprise exposing the layer to a gas comprising oxygen gas (O₂) at a temperature of between about 800° C. and about 1100° C.

20. The method of claim 14, wherein the further annealing comprises exposing the layer to an inert gas at a temperature of between about 800° C. and about 1100° C.
